(19) United States
(12) Patent Application Publication
(10) Pub. No.: US 2026/0191068 A1
(43) Pub. Date: Jul. 2, 2026

(54) LASER-ASSISTED REFLOW FOR SELECTIVE HEATING USED WITH A LOW TEMPERATURE TRAY

(71) Applicant: Intel Corporation, Santa Clara, CA (US)

(72) Inventors: Sangeon LEE, Chandler, AZ (US); Moataz ABDULHAFEZ, Chandler, AZ (US); Tingting GAO, Chandler, AZ (US); Xiao LU, Chandler, AZ (US); Jean Bosco KANA KANA, Chandler, AZ (US)

(21) Appl. No.: 19/002,121

(22) Filed: Dec. 26, 2024

(51) Int. Cl. H01L 23/00

(52) U.S. Cl. CPC H10W 72/0711; H10W 72/0198; H10W 72/072; H10W 72/012; H10W 72/07141; H10W 72/07188; H10W 72/07236

(57) ABSTRACT

A system for solder processing a semiconductor device can be performed with LAR (laser assisted reflow) with a low temperature matrix tray. The system includes a tray shield to shield the matrix tray from excessive heat exposure during solder reflow. The shielding prevents heat exposure past the point of warpage during reflow due to heat exposure from laser light. The LAR has a laser source that provides collimated laser light to induce solder reflow in the target semiconductor device.

### FIELD

Descriptions are generally related to reflow processing, and more particular descriptions are related to reflow processing trays.

### BACKGROUND

Semiconductor products are handled in trays that meet the JEDEC (Joint Electron Device Engineering Council) standard. The standard trays are LCP (liquid crystal polymer) trays made from molding compounds, and are designed to endure temperatures sufficient for mass reflow, which is particularly useful for ball attachment (BA) applications.

PES (poly-ether sulfone) trays are less expensive than LCP trays, but they do not have the same thermal performance as LCP trays. More specifically, PES trays experience damaging warpage when exposed to the temperatures for the times used for mass reflow (MR). Mass reflow is typically accomplished with a quartz heater to melt solder and a fan to distribute the heat through convective transfer. However, mass reflow requires a preheating phase to heat the surrounding air, which takes a considerable amount of time to reach the point where the solder melts.

Additionally, because the MR process depends on convective heat, not all the energy is effectively used for melting the solder, resulting in wasted energy. The convective heating results in prolonged exposure of the tray to high temperature for the reflow solder processing. Such prolonged exposure can result in permanent thermal deformation of PES trays.

### BRIEF DESCRIPTION OF THE DRAWINGS

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIG. 1 is a block diagram of an example of a system for solder processing.

FIGS. 2A-2B are diagrams of an example of a solder processing assembly.

FIGS. 3A-3B are diagrams of an example of soldering processing of a BGA solder ball array.

FIGS. 4A-4B are diagrams of an example of soldering processing of discrete components.

FIGS. 5A-5B are diagrams of an example of soldering processing of semiconductor chips.

FIG. 6 is a diagram of an example of a solder processing tray and shield assembly.

FIG. 7 is a diagram of an example of an LAR unit.

FIGS. 8A-8B are diagrams of an example of soldering processing shielding with a shield on the tray.

FIG. 9 is a diagram of an example of soldering processing shielding with a shield on the laser head.

FIGS. 10A-10C are diagrams of an example of soldering processing shielding with a coating on the tray.

FIGS. 11A-11B are diagrams of an example of soldering processing with a lifter unit.

FIG. 12 is a flow diagram of an example of process for solder processing.

FIG. 13 is a diagram of an example of heat energy comparison between LAR and MR.

Descriptions of certain details and implementations follow, including non-limiting descriptions of the figures, which may depict some or all examples, and well as other potential implementations.

### DETAILED DESCRIPTION

As described herein, a system for solder processing can be performed with LAR (laser assisted reflow) with a low temperature matrix tray assembly. The LAR has a laser source that provides collimated laser light to induce solder reflow in the target held by the tray. The system includes a tray shield to shield the matrix tray from excessive heat exposure during solder reflow. The shielding shields the tray from laser light to reduce the heat exposure, which prevents the tray from heating past the point of warpage during reflow. LAR provides the heat necessary for solder reflow in much less time than convective heat mass reflow. With the reduced time for solder reflow from LAR, the solder processing time can be significantly reduced. Additionally, with the reduced solder processing time combined with the shielding for the tray, the amount of time the tray is exposed to heat stress is significantly reduced.

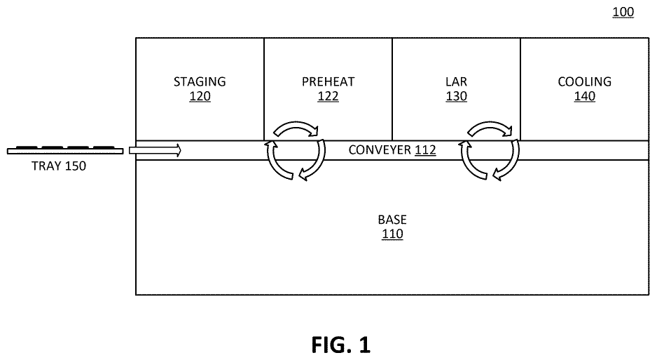

FIG. 1 is a block diagram of an example of a system for solder processing. System 100 illustrates an LAR system for soldering a semiconductor unit in a tray. In one example, system 100 represents a single machine for solder reflow processing. In one example, system 100 represents a combination of machines for solder reflow processing.

Base 110 represents the base and housing of the processing equipment. Conveyer 112 represents a moving pathway through the processing equipment, as represented by the circular arrows. Conveyer 112 represents the pathway of the assembly line. In one example, the processing machine has multiple portions, including staging 120, LAR 130, and cooling 140. The processing machine can optionally include a preheating portion. Conveyer 112 provides a pathway through the various portions of the solder processing.

Staging 120 represents a portion where one or more solder targets are mounted in trays. Tray 150 represents a matrix tray to hold a semiconductor device for solder processing. The scale of tray 150 to the solder processing machinery is not necessarily to scale. The semiconductor device can include a PCB (printed circuit board) or other substrate that receives a chip, as well as one or more IC (integrated circuit) chips, and potentially discrete components. In one example, the semiconductor device or device for solder processing includes a BGA (ball grid array) to solder to a PCB/substrate.

Preheat 122 represents an optional heating chamber for a preheating stage prior to laser operation. Preheating the semiconductor device and the matrix tray prior to exposure to the laser light can heat up the solder to reduce the energy needed from the laser to induce solder reflow. However, preheating may be less preferred in some implementations, as it generally involves convective heating, which is less precise and efficient compared to LAR.

In one example, preheat 122 represents a stage of heating in a chamber before entering the LAR chamber. In one example, preheating involves lifting the units above the tray to reduce heat exposure to the tray. The process preheats the units via conductive heating to a specific set point. In one example, the system flattens the preheated unit substrates via heating plus a vacuum. After heating and flattening, the pedestal or table moves via ball screw linear translation to the laser reflow area of LAR 130.

LAR 130 represents a chamber with a laser-assisted reflow laser source to induce solder reflow in the target. In one example, the LAR laser provides highly collimated laser light that has high directionality to heat specific portions of the target. In one example, LAR 130 generates a very short laser irradiation time, resulting in substantially thin, uniform, and continuous IMC (intermetallic compound) layer formation on the solder ball.

Cooling 140 represents a cooling stage to control temperature reduction of tray 150 after it has been through solder reflow. In one example, tray 150 is a low-temperature tray. In one example, tray 150 is made of a PES (poly-ether sulfone) material. PES is much less expensive than LCP (liquid crystal polymer) and has much lower heat tolerance. System 100 enables the use of PES trays due to selective heating.

System 100 can provide a highly energy efficient approach to LAR soldering that safeguards a low-temperature tray (such as PES) from heat related damage. System 100 includes shielding to shield tray 150 from heat exposure from the laser light during the solder reflow during LAR 130. In one example, the shielding includes tray shielding. In one example, the shielding includes unit level masking. In one example, the shielding includes both tray shielding and unit level masking.

In one example, the shielding provides simultaneous or sequential joining of two different connections in a single step. Thus, system 100 can enable solder processing that can handle multiple interconnections. The processing machine of system 100 can be compact relative to a mass reflow machine. A mass reflow machine needs to have a long internal pathway to expose the target to the needed heat for an extended period of time. LAR is very short relative to mass reflow, which allows for an assembly line with a decreased length.

System 100 can provide a package or a processing assembly for solder processing. The package or assembly includes the tray and the semiconductor device that is the target for solder processing. With the shielding and LAR processing in system 100, the package experiences a substantial decrease in heat exposure relative to mass reflow. Additionally, system 100 can improve device reliability with improved solder joints due to more uniform nucleation of the IMC layer. System 100 reduces package distortion, which can reduce the need or reliance for stiffeners, seeing that the package can maintain shape without warping.

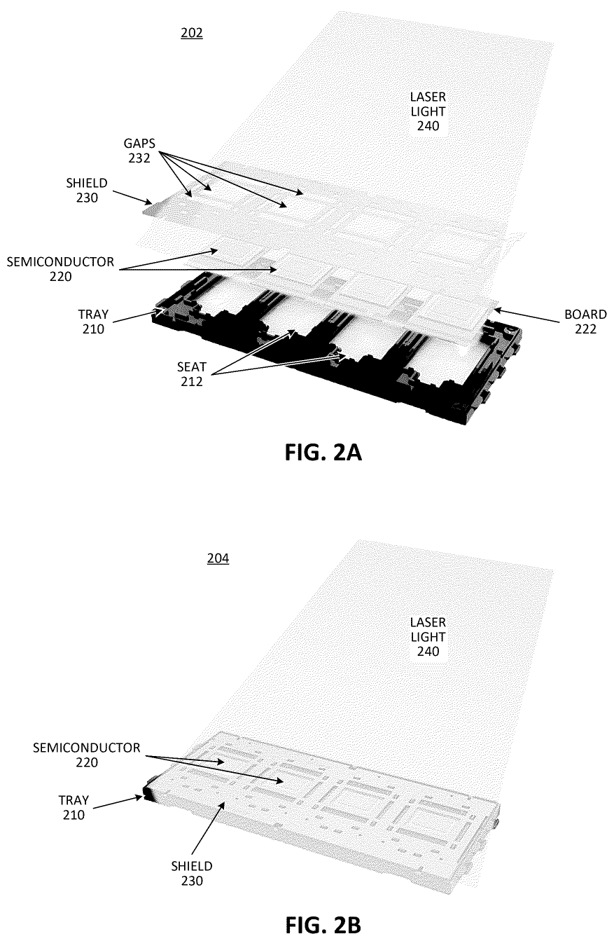

FIGS. 2A-2B are diagrams of an example of a solder processing assembly. System 202 represents a matrix tray assembly for use in a system in accordance with an example of system 100. System 204 represents an example of system 202 as assembled for solder processing.

Referring to system 202, tray 210 represents a matrix tray. In one example, tray 210 is a low temperature tray. In one example, tray 210 is a PES tray. Tray 210 includes multiple seats 212, which represent locations to receive and hold a semiconductor device for solder processing. The example of system 202 illustrates four seats 212. Tray 210 can include more or fewer seats. The use of multiple seats 212 enables tray 210 to hold an array of semiconductor devices for solder processing.

System 202 illustrates semiconductor 220, which represents the semiconductor device that is the target for solder processing. Board 222 represents a substrate or PCB to which semiconductor 220 is mounted, or will be mounted through solder processing. For example, semiconductor 220 can be mounted to board 222 through reflow solder processing of a BGA (ball grid array) of semiconductor 220.

In one example, semiconductor 220 represents a component having a BGA for solder processing. In one example, the component can be an HBM (high-bandwidth memory) stack or other die stack. Such a stack of dies can include a chip with chiplets. A die stack refers to a component where multiple bare dies are stacked one on the other. A bare die refers to an IC chip without molding on it. In one example, the component can be a single bare die. In one example, the component can be a molded die, whether a molded component with a single die, or a molded component having multiple dies in it.

System 202 includes shield 230, which provides shielding for tray 210. In one example, shield 230 not only shields tray 210, it also masks the assembly to provide selective heating of the assembly. Shield 230 covers tray 210 to prevent exposure to the laser light during the LAR phase of processing. Gaps 232 represent openings in shield 230. Laser light 240 represents the laser light generated to irradiate the processing assembly.

In one example, gaps 232 provide unit masking, with selective openings for portions of semiconductor that need solder processing. For purposes of description, the term “unit” can refer to the individual semiconductor units to be exposed to solder processing. Thus, unit masking can refer to selective exposure to a semiconductor component and board to be processed. The term unit can alternatively refer to the assembly of the tray and the semiconductor units to pass through the solder processing stages.

Referring to system 204, shield 230 is mounted to tray 210. Semiconductor 220 is exposed to laser light 240 through shield 230. Shield 230 prevents tray 210 from exposure to laser light 240, even as the laser light heats up semiconductor 220 to induce solder reflow.

The LAR-based reflow of system 202 provides multiple advantages. With shield 230, the system can locally reflow the target component without exposing the majority of the sample to high temperatures. The LAR process provides a highly accelerated reflow time and fast cooling rate relative to mass reflow. Experimentation indicates that LAR can be 50 times quicker, or even more, compared to MR (mass reflow) processing. The increased processing speed allows the entire solder process to be highly transient, enabling significantly different reflow parameters relative to MR processes.

Shield 230 enables the use of LAR processing, by masking tray 210, enabling the use of low temperature trays without causing thermal damages. A low temperature tray can refer to a tray that has a glass transition temperature (Tg) that is lower than the peak temperature required for the solder balls. For example, SAC (Sn—Ag—Cu (tin-silver-copper)) solder can be processed with temperatures in the mid 200's C, where PES trays have a Tg of approximately 160 C.

The shielding and short time of the LAR processing enables the use of a PES tray or other tray having a Tg lower than the solder processing temperature, which would other warp or suffer permanent damage from convective solder processing. The LAR stage can provide precise, localized heating and non-contact processing, along with rapid temperature changes. The shielding enables broad laser exposure, as opposed to needing multiple exposures in very narrow or focused process. Thus, in one example, the laser beam can uniformly irradiate both the trays and the semiconductor components with equal intensity.

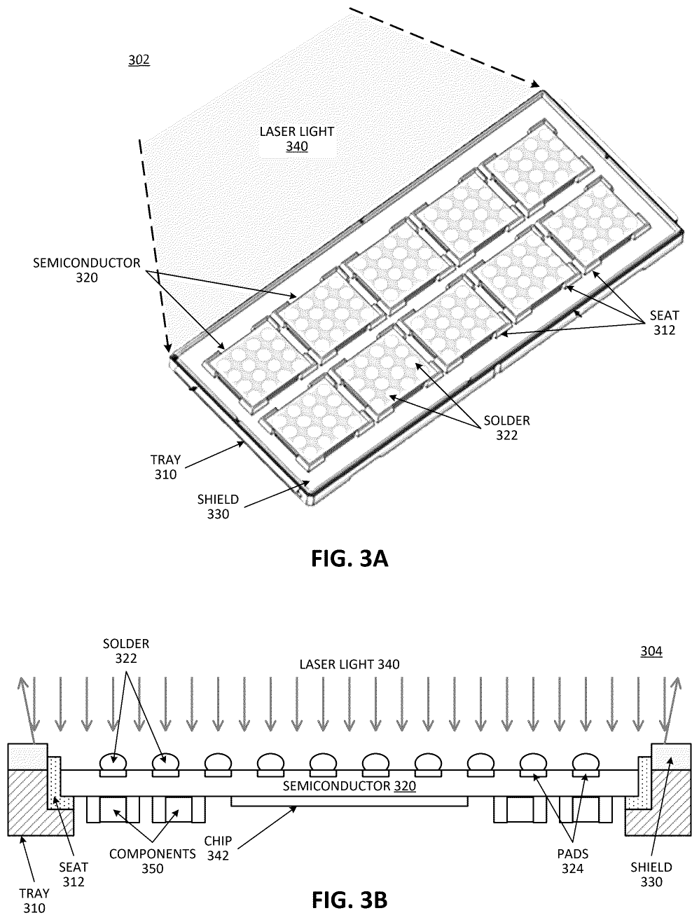

FIGS. 3A-3B are diagrams of an example of soldering processing of a BGA solder ball array. System 302 represents a matrix tray assembly for use in a system in accordance with an example of system 100. System 304 represents an example of a cutaway view of system 302.

Referring to system 302, tray 310 represents a matrix tray, which can be a low temperature tray, such as a PES tray. Tray 310 includes multiple seats 312, which represent locations to receive and hold a semiconductor device for solder processing. The example of system 302 illustrates ten seats 312. Tray 310 can include more or fewer seats. The use of multiple seats 312 enables tray 310 to hold an array of semiconductor devices for solder processing.

System 302 illustrates semiconductor 320, which represents the semiconductor device that is the target for solder processing. Solder 322 represents a BGA of semiconductor 320 to solder with the LAR processing. System 302 includes shield 330, which provides shielding for tray 310.

Referring to system 304, shield 330 is mounted to tray 310. Seat 312 can be considered part of tray 310, to hold semiconductor 320 for solder processing. Laser light 340 irradiates semiconductor 320 through shield 330. Shield 330 prevents tray 310 from exposure to laser light 340, as illustrated by the reflection arrows.

Laser light 340 irradiates solder 322, adhering to pads 324. Chip 342 represents a chip that can be mounted to the surface of semiconductor 320 opposite the surface exposed to laser light 340. Components 350 represent discrete components (e.g., surface mount capacitors) mounted to the same side of semiconductor 320 as chip 342.

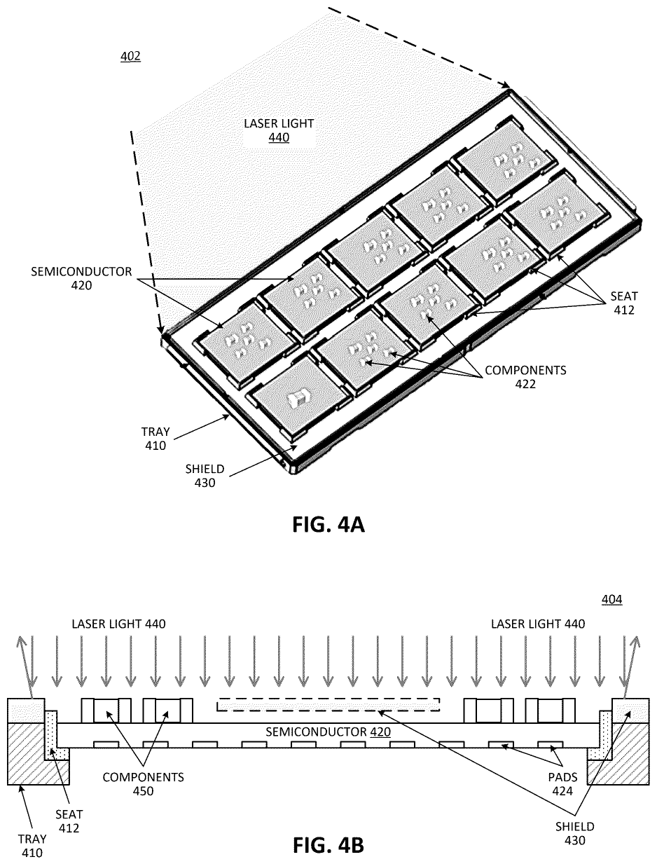

FIGS. 4A-4B are diagrams of an example of soldering processing of discrete components. System 402 represents a matrix tray assembly for use in a system in accordance with an example of system 100. System 404 represents an example of a cutaway view of system 402.

Referring to system 402, tray 410 represents a matrix tray, which can be a low temperature tray, such as a PES tray. Tray 410 includes multiple seats 412, which represent locations to receive and hold a semiconductor device for solder processing. The example of system 402 illustrates ten seats 412. Tray 410 can include more or fewer seats. The use of multiple seats 412 enables tray 410 to hold an array of semiconductor devices for solder processing by laser light 440 of an LAR stage.

System 402 illustrates semiconductor 420, which represents the semiconductor device that is the target for solder processing. Semiconductor 420 is illustrated having discrete components mounted to its target surface, represented by components 422. While system 402 illustrates capacitor components, it will be understood that components 422 can represent any surface mount components, including components of different types. System 402 includes shield 430, which provides shielding for tray 410.

Referring to system 404, shield 430 is mounted to tray 410. Seat 412 can be considered part of tray 410, to hold semiconductor 420 for solder processing. Laser light 440 irradiates semiconductor 420 through shield 430. Shield 430 prevents tray 410 from exposure to laser light 440, as illustrated by the reflection arrows.

Laser light 440 irradiates components 422, inducing solder reflow to adhere the components to semiconductor 420. Pads 424 represent pads for a BGA on a surface of semiconductor 420 opposite to the side exposed to laser light 440. In one example, part of shield 430 covers the area of semiconductor 420 that does not need to be exposed to laser light to induce solder reflow to mount components 450.

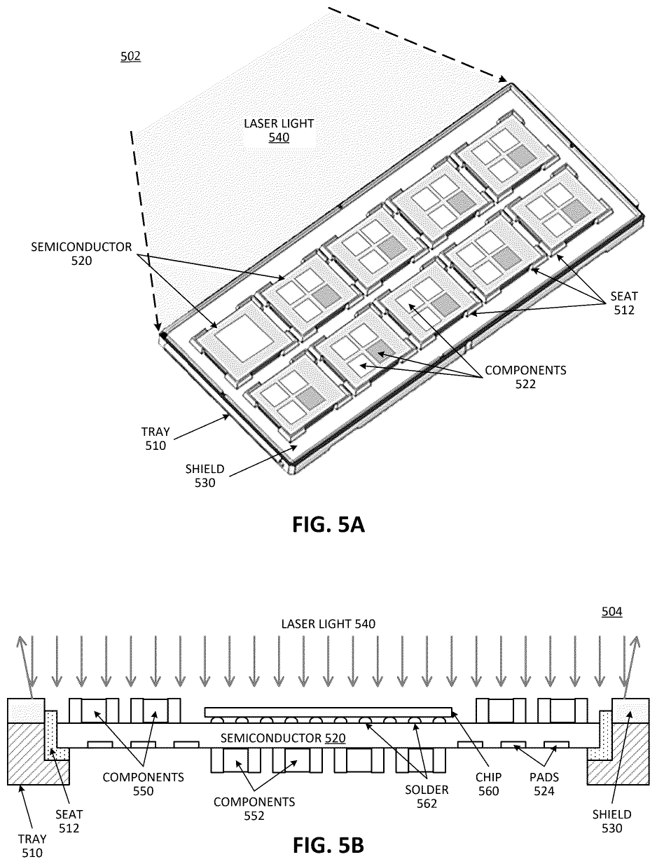

FIGS. 5A-5B are diagrams of an example of soldering processing of semiconductor chips. System 502 represents a matrix tray assembly for use in a system in accordance with an example of system 100. System 504 represents an example of a cutaway view of system 502.

Referring to system 502, tray 510 represents a matrix tray, which can be a low temperature tray, such as a PES tray. Tray 510 includes multiple seats 512, which represent locations to receive and hold a semiconductor device for solder processing. The example of system 502 illustrates ten seats 512. Tray 510 can include more or fewer seats. The use of multiple seats 512 enables tray 510 to hold an array of semiconductor devices for solder processing by laser light 540 of an LAR stage.

System 502 illustrates semiconductor 520, which represents the semiconductor device that is the target for solder processing. Semiconductor 520 is illustrated having chips and discrete components mounted to its target surface, represented by chip 560 and components 522. System 502 illustrates a mix of chips and surface mount components, which can represent any combination of components to be mounted to semiconductor 520 during solder reflow. System 502 includes shield 530, which provides shielding for tray 510.

Referring to system 504, shield 530 is mounted to tray 510. Seat 512 can be considered part of tray 510, to hold semiconductor 520 for solder processing. Laser light 540 irradiates semiconductor 520 through shield 530, induing solder reflow to mount chip 560 and components 550 to semiconductor 520. Shield 530 prevents tray 510 from exposure to laser light 540, as illustrated by the reflection arrows.

Laser light 540 irradiates chip 560, inducing flow of solder 562 to adhere the chip to pads (not specifically illustrated) on semiconductor 520. Components 550 represent components on a surface of semiconductor 520 exposed to laser light with chip 560. Components 552 represent components on a surface of semiconductor 520 opposite to the side exposed to laser light 540. In one example, semiconductor 520 includes pads 524 on the back side of the substrate. In one example, both sides of semiconductor 520 are processed separately to solder reflow with an LAR stage.

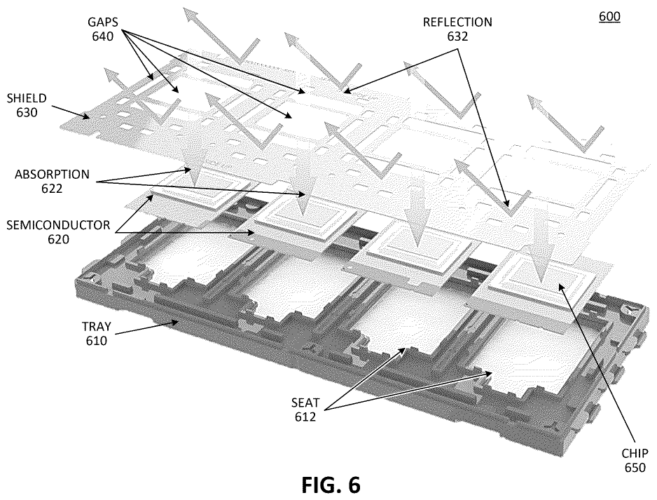

FIG. 6 is a diagram of an example of a solder processing tray and shield assembly. System 600 represents a matrix tray assembly for use in a system in accordance with an example of system 100.

Tray 610 represents a matrix tray. In one example, tray 610 is a low temperature tray. In one example, tray 610 is a PES tray. Tray 610 includes multiple seats 612, which represent locations to receive and hold a semiconductor device for solder processing. The example of system 600 illustrates four seats 612. Tray 610 can include more or fewer seats. The use of multiple seats 612 enables tray 610 to hold an array of semiconductor devices for solder processing.

System 600 illustrates semiconductor 620, which represents the semiconductor device that is the target for solder processing. Chip 650 represents a chip to mount to a substrate or PCB of semiconductor 620. In one example, a BGA of chip 650 mounts to the substrate of semiconductor 620.

System 600 includes shield 630, which provides shielding for tray 610. In one example, shield 630 not only shields tray 610, it also masks the assembly to provide selective heating of the assembly. Shield 630 covers tray 610 to prevent exposure to the laser light during the LAR phase of processing. Gaps 640 represent openings in shield 630. In system 600, the assembly is exposed to laser light for LAR processing. In one example, gaps 640 provide unit masking, with selective openings for portions of semiconductor that need solder processing.

Absorption 622 represents the laser light that passes through gaps 640 in shield 630 to irradiate semiconductor 620, inducing solder reflow to accomplish the solder processing. Reflection 632 represents the laser light that reflects off shield 630, preventing excessive heating of tray 610.

The tray masking provides thermal shielding to enable the use of LAR processing with tray 610, while effectively reducing the amount of heat transferred to the tray from the laser. Shield 630 provides a thermal barrier to reduce the accumulation of surface temperature on tray 610 when system 600 is exposed to laser energy. The thermal barrier impedes IR (infrared) laser beam irradiation, which prevents both immediate localized melting and gradual long-term deformation of tray 610.

In one example, system 600 provides unit level masking, which allows for selective heating, even down to individual units. With selective masking, the laser would affect the areas intended for reflow soldering, as the mask prevents the laser from reaching other sections. In one example, the laser is a highly collimated IR laser light. With such laser light, the mask can facilitate soldering at extremely fine scales, even below a micrometer. A highly collimated laser light refers to emitting a laser beam having its rays running parallel to each other with very little spread as they travel. A perfectly collimated beam would maintain its focus indefinitely without spreading out. As a result, using a mask to shield certain areas achieves exceptional precision. It can be employed to specifically shield areas, leading to a discernible temperature variation between the covered and exposed regions even down to a sub-micron level. Such masking provides selective heating that enables the concurrent or sequential bonding of two different types of interconnections, such as die, DSC (discrete component), or ball attachment in one single process.

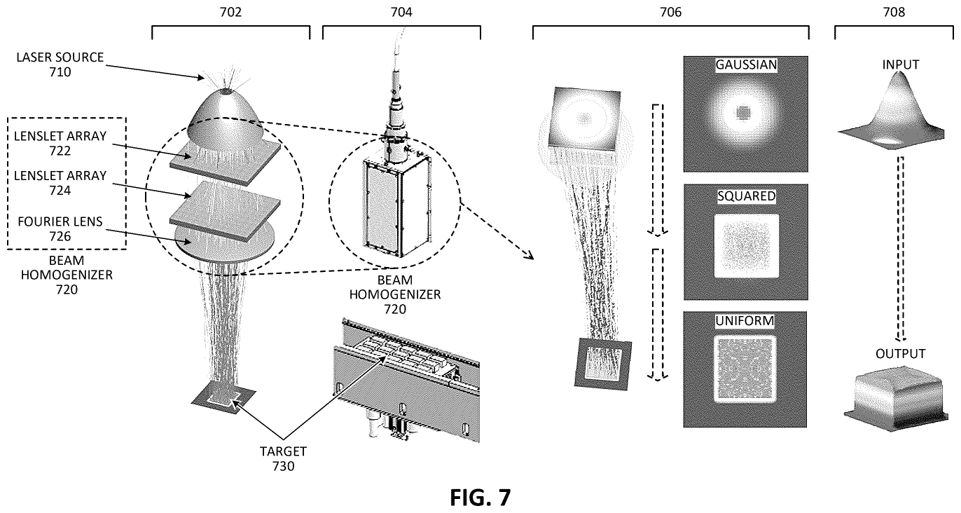

FIG. 7 is a diagram of an example of an LAR unit. The diagram illustrates a laser assembly for LAR processing in accordance with an example of system 100. Diagram 702 illustrates components of the laser itself. Diagram 704 illustrates the laser assembled. Diagram 706 illustrates the transmission of the laser light. Diagram 708 illustrates the transition from input to output of the laser signal.

Diagram 702 illustrates the laser. Laser source 710 provides laser light to beam homogenizer 720. In one example, beam homogenizer 720 includes lenslet array 722, lenslet array 724, and Fourier lens 726. The components of beam homogenizer 720 achieve a uniform distribution of energy intensity across the entire JEDEC tray area. The LAR system's homogenized rectangular laser beam delivers consistent heat intensity to the substrate's top surface, creating a uniform temperature profile over the area of interest. Target 730 represents the area of interest for solder processing. The area of interest is the semiconductor product for solder processing.

Laser source 710 represents a high-power laser source that provides laser energy to beam homogenizer 720. Beam homogenizer 720 takes the laser energy and creates a highly collimated laser signal. In one example, beam homogenizer 720 can accommodate a full JEDEC (Joint Electron Device Engineering Council) standard tray (350 mm×150 mm), maintaining over 90% uniformity across the entire zoom range. Thus, the laser can treat the entire tray in a single laser shot, significantly enhancing the efficiency of the production cycle.

Diagram 704 illustrates the assembled laser and a close-up of target 730. Beam homogenizer 720 collimates laser light to irradiate target 730. In diagram 702, the target is illustrated as a semiconductor unit. In diagram 704, the target is illustrated as the tray with an array of semiconductor units.

Diagram 706 illustrates that the laser signal starts as a Gaussian signal passing through the lens arrays. The arrays transform the laser signal into a squared signal. The signal is then transformed into a uniform laser signal. The uniform, collimated signal impinges on the target.

The LAR system can overcome reliability and throughput issues present with conventional MR and TCB (thermal compression bonding) technology. Traditional lasers emit a beam with a Gaussian intensity distribution, where the majority of the energy is focused at the center, leading to potential thermal damage or localized melting of thin silicon layers during the reflow process. Diagram 708 illustrates a three-dimensional representation of the Gaussian input converted to a homogenized, uniform distribution output.

Laser energy transfers through electrons and phonons, with photons imparting energy to the material's atoms. The target material's atoms absorb the laser energy, resulting in heating. Initially, the laser beam's energy is absorbed predominantly by the solder ball, which then conducts heat to the bottom of the solder and pad. Consequently, the solder melts, forming a robust bond between the ball and the substrate. Since the target is exposed to heat for only a brief period, thermomechanical stress and warpage are significantly reduced.

Use of LAR as described herein will result in a uniform and continuous IMC layer. During the LAR process, the IMC layer forms and solidifies rapidly, leaving insufficient time for secondary diffusion and growth. Experimentation indicates that the shorter laser soldering duration achieved with LAR results in a thinner, more uniform IMC layer.

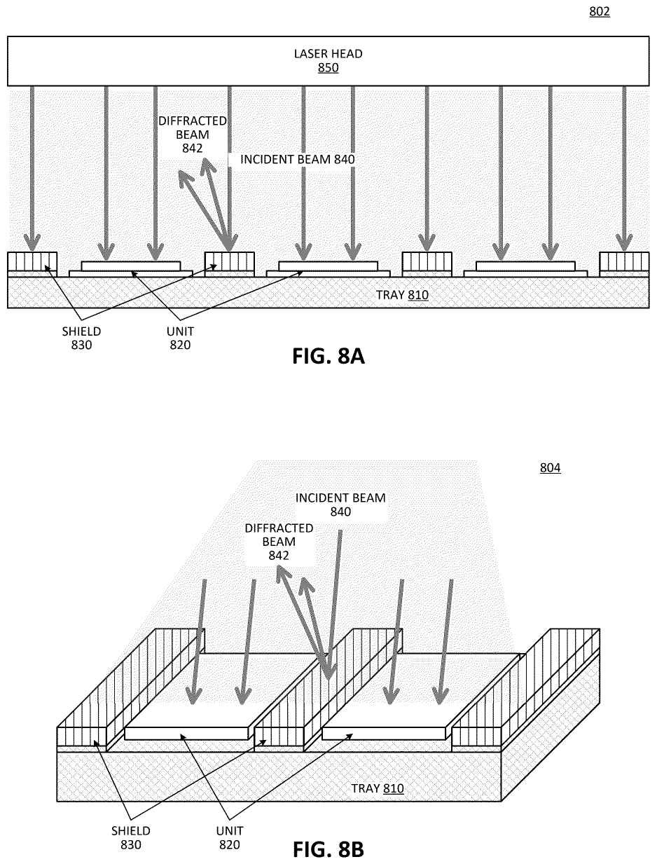

FIGS. 8A-8B are diagrams of an example of soldering processing shielding with a shield on the tray. Diagram 802 represents a cutaway view of matrix tray assembly for use in a system in accordance with an example of system 100. Diagram 804 represents an example of a perspective view of diagram 802.

Diagram 802 illustrates tray 810, which represents a matrix tray in accordance with any example herein. Tray 810 holds one or more units 820, which represent semiconductor devices for solder processing. Shield 830 represents shielding for tray 810. Diagram 804 illustrates the same components to illustrate the concept from a different perspective.

Laser head 850 represents an LAR laser source, which irradiates tray 810 with laser energy. Incident beam 840 represents the collimated laser light directed to tray 810 by laser head 850. Incident beams 840 that pass through shield 830 to units 820 are absorbed by the units to heat them up, causing the solder to flow.

Incident beams 840 that strike the surface of shield 830 reflect off the shield as diffracted beam 842. Units 820 absorb the laser light that reaches them. Diffracted beam 842 does reach tray 810. Thus, the laser energy that is absorbed by tray 810 is minimal, while the energy absorbed by the semiconductor units allows the solder to flow.

In one example, the matrix tray is made of PES, which is amorphous, high-performance thermoplastic resin. Because PES is amorphous, mold shrinkage is low and is suitable for applications requiring close tolerances and little dimensional change over some degree of temperature range. PES can be used to make trays that comply with JEDEC standards. However, due to its relatively low temperature tolerance, the shielding of diagram 802 enables its use in reflow processing, with LAR operation instead of MR.

In one example, shield 830 represents a plate-type laser shielding mask that is coupled to tray 810. Thermal shielding elements can be directly affixed to the tray, allowing the tray's surface to be shielded, which reflects most of the laser heat before it reaches the tray's surface. The area exposed through shield 830 primarily passes through to units 820, whose surfaces absorb the laser beams, conducting heat from the surface to the interior of the object. Consequently, the temperature of the object increases in response to heat transfer from the laser energy.

In one example, the laser's wavelength (960 nm) is significantly smaller than the size of the opening through shield 830. Thus, the beams within the exposed region are focused on heating the unit rather than the tray. The effectiveness of the tray masking was confirmed by comparing the peak temperatures from the experimental data. Thermal analysis assessed the laser's impact on the tray for a system in accordance with diagram 802. The transmitted thermal energy from the laser head increased the tray's temperature above 300 C when no shielding was used. However, when heat shielding was implemented to safeguard the tray, the highest temperature recorded on the tray dropped to approximately 100 C, which is substantially lower than the glass transition temperature of PES material.

In one example, shield 830 represents patterned aluminum plates, which deflect heat very efficiently to guard temperature-sensitive areas. Shield 830 can alternatively be composed of other heat-insulating materials, such as metal-based alloys, aluminum-based alloys, titanium-based alloys, or nickel-based alloys.

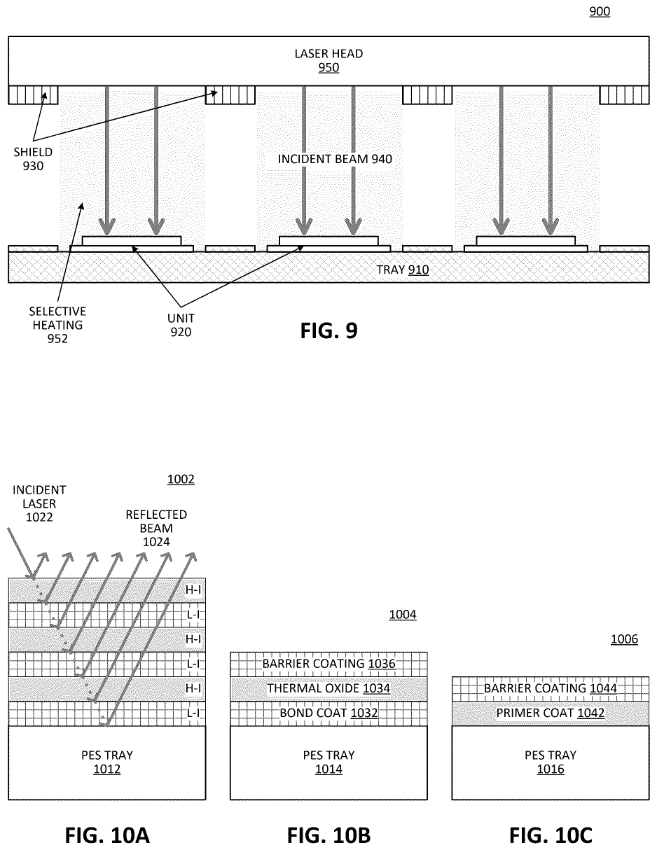

FIG. 9 is a diagram of an example of soldering processing shielding with a shield on the laser head. Diagram 900 represents a cutaway view of matrix tray assembly for use in a system in accordance with an example of system 100.

Diagram 900 illustrates tray 910, which represents a matrix tray in accordance with any example herein. Tray 910 holds one or more units 920, which represent semiconductor devices for solder processing. Shield 930 represents shielding for tray 910. More specifically, shield 930 can be implemented as a laser mask to direct light to specific target areas, while not exposing the unit to the collimated laser light.

Laser head 950 represents an LAR laser source, which irradiates tray 910 with laser energy. Incident beam 940 represents the collimated laser light directed to tray 910 by laser head 950. Incident beams 940 that pass through shield 930 to units 920 are absorbed by the units to heat them up, causing the solder to flow.

In one example, shield 930 represents a specialized masking attachment for laser head 950. Shield 930 provides laser light from the source to units 920. With the shielded laser emission, the shielding enables selective heating 952.

The attachment is coupled to the output of the LAR laser source. The attachment can be referred to as a cut-out fixture directly connected to laser head 950. The fixture can include a solid partition at its center, where the laser head is positioned. In one example, shield 930 is designed as a mesh, where the fixture prevents the laser from passing beneath the partition. In one example, shield 930 represents a heat shield made from stainless steel sheet metal due to its reflectivity, emissivity, thermal conductivity, and specific heat capacity. Stainless steel is also cost-effective, durable, and adaptable to customization. Other metals or thermal insulation coating can be employed.

The mesh-style cut-out fixture enables effective laser irradiation while avoiding the heating of tray 910. Shield 930 allows for targeted laser exposure that is independent of the position of the tray or the unit, directing the laser straight at the unit. The mesh fixture's design is straightforward, enhancing contrast and delivering a more precise distribution of the laser. The light is absorbed by the edges of the fixture, while the laser passes through the openings, heating the target object rather than the tray. Consequently, the laser emitted by the fixture is strictly vertical, resulting in a more focused beam, while reducing or eliminating sideways dispersion.

Adjusting the laser's power or altering the masking design can modify the laser's shape and size. Diagram 900 can provide a highly directional beam, increased output power, and durability. Such features apply well to a range of soldering applications.

FIGS. 10A-10C are diagrams of an example of soldering processing shielding with a coating on the tray. Diagram 1002, diagram 1004, and diagram 1006 represent different versions of coatings on a matrix tray.

In general, coatings on the matrix tray can include materials such as carbon fiber or carbon coatings or TBC (thermal barrier coating) materials such as YSZ (yttria-stabilized zirconia) or an oxidation-resistant bond coat (BC). Coatings provide high reflection to reflect the laser light off the tray instead of being absorbed into the tray. With a tray coating, the tray itself can act as the tray and as the tray shield, without need for another shielding component to be included in the assembly.

A proper heat shield coating can efficiently reflect laser energy. HR coatings are thin films applied to optical components to control their reflectance and transmittance properties. The coatings work by interfering with light waves, resulting in constructive or destructive interference, depending on the coating thickness and the wavelength of light. There are several ways to apply highly reflective coating on a PES tray.

Diagram 1002 illustrates PES tray 1012 with a coating made of alternating layers of high-index (H-I) material and low-index (L-I) material. Incident laser 1022 partially reflects off the interface or transition between low index and high index layers. Reflected beam 1024 represents the reflection of the laser through the different layers of coating.

Diagram 1004 illustrates PES tray 1014 with a coating made of a thin dielectric or metallic layer applied to reflective optical systems, such as mirrors, which increases the reflectance of the surface to deflect a laser beam from the surface while reducing transmission, absorption, and scatter.

The metallic coating can include bond coat 1032, thermal oxide 1034, and barrier coating 1036. Bond coat 1032 bonds the coating to PES tray 1014. Thermal oxide 1034 represents a dielectric heat-resistant coating. Barrier coating 1036 represents a metallic surface.

Metallic coatings offer high reflectance (HR) over a wide range of wavelengths, while dielectric coatings provide lower reflectance and can be tailored to specific wavelengths. Metallic mirror coatings are used to create reflective components for many applications. Laser applications require higher reflectivity than those offered from standard metallic mirror coatings.

Metallic surfaces reflect light because loosely attached electrons freely oscillate with incident light waves without much impedance or hindrance, but all metals will absorb some amount of incident laser light. Examples of metallic coatings include aluminum (Al), gold (Au) and silver (Ag).

Dielectric HR coatings reflect laser based on constructive interference during Fresnel reflections. Constructive interference is caused by alternating layers of high refractive and low refractive index materials with thicknesses specifically chosen to maximize reflectivity at a given wavelength range, as illustrated in diagram 1002. In a λ/4 dielectric mirror, also known as a Bragg mirror, the thickness of each layer corresponds to a quarter of the design wavelength. Dielectric overcoats also improve handling of metallic mirrors, increase the durability of the metal coating, provide protection from oxidation, and enhance the reflectance of the metal coating in specific spectral regions. Dielectric coatings such as thermal oxide 1034 are composed of materials such as titanium dioxide, tantalum pentoxide, and silicon dioxide.

Bond coat 1032 provides an intermediary layer between the substrate of PES tray 1014 and the ceramic topcoat, represented by barrier coating 1036. The bond coat acts as a thermal barrier and provides adhesion. In general, MCrAlY (e.g., NiCoCrAlY) alloys are commonly used due to their excellent oxidation resistance. Bond coats are dense and possess good adhesion to both the substrate and the topcoat.

The ceramic topcoat is the outermost layer of the TBC, responsible for providing thermal insulation and heat reflection. Common materials include yttria-stabilized zirconia (YSZ), pyrochlores, and rare earth oxides. The topcoat often exhibits a highly porous, columnar microstructure, which enhances thermal insulation by trapping air within the pores.

TGO is an oxide layer that forms at the interface between the bond coat and the ceramic topcoat of a TBC. While TGO serves as a protective barrier against further oxidation of the bond coat and substrate, excessive TGO growth can lead to TBC failure by reducing adhesion between the layers. The composition of TGO typically includes oxides of elements present in the bond coat material, such as aluminum and chromium. The thickness of TGO can vary depending on the exposure conditions but is generally limited to a few micrometers to maintain TBC performance. Excessive TGO thickness can compromise the TBC's thermal insulating properties and mechanical integrity.

Diagram 1006 illustrates PES tray 1016 with a coating made of a heat shield paint. Heat shield paints operate on a similar principle to metallic coatings, reflecting infrared rays that pass through the topcoat with a specialized primer coat. Primer coat 1042 represents a primer on the tray, where barrier coating 1044 represents a paint or coating on the primer. The paints are engineered to reflect infrared rays more effectively than standard paints of the same color, with higher reflectance correlating to a stronger heat shielding effect. The use of multilayer films amplifies the heat shielding capability, reflecting laser energy to keep the PES tray cool. The coatings can be applied to the PES tray using methods such as spray coating, dipping, or brushing.

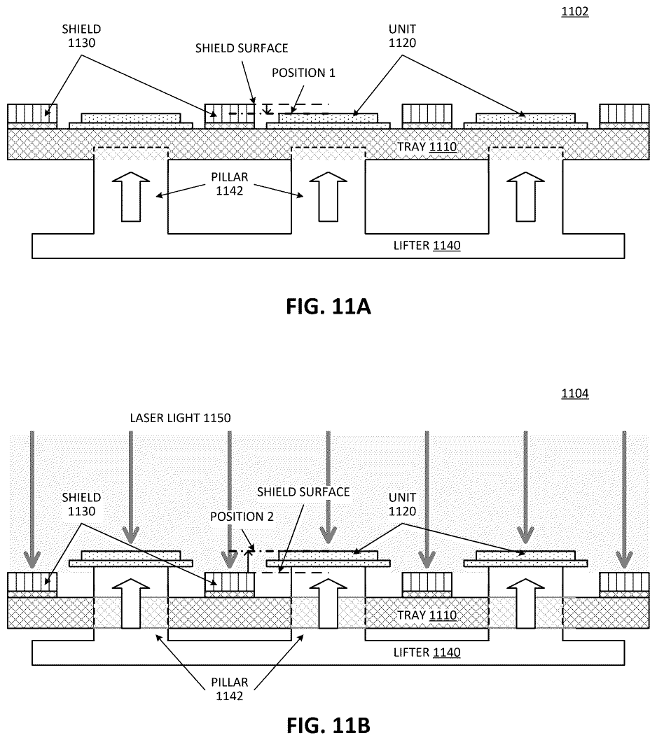

FIGS. 11A-11B are diagrams of an example of soldering processing with a lifter unit. Diagram 1102 represents a cutaway view of matrix tray assembly for use in a system in accordance with an example of system 100. Diagram 1104 represents an example of diagram 1102 in a position with the semiconductor devices raised.

Diagram 1102 illustrates tray 1110, which represents a matrix tray in accordance with any example herein. Tray 1110 holds one or more units 1120, which represent semiconductor devices for solder processing. Shield 1130 represents shielding for tray 1110.

In one example, diagram 1102 includes lifter 1140, which represents a device to lift units 1120 above the level of shield 1130. Diagram 1102 illustrates the shield surface, which is the top surface of shield 1130. Position 1 illustrates a top surface of unit 1120. Pillars 1142 portions of lifter 1140 that can lift units 1120.

Diagram 1104 illustrates tray 1110 with shield 1130 over the tray. In diagram 1104, lifter 1140 has pillar 1142, which pushes up units 1120 above the shield surface. Position 2 represents a position above the shield surface, where units 1120 are raised above shield 1130.

Lifter 1140 represents a lifter mechanism, which can facilitate more uniform laser light reception by the units. Raising the units above the level of shield 1130 can avert undesirable laser diffraction effects, such as scattering and diffuse reflection from the edges of shield 1130. Diffuse reflection typically occurs on rough surfaces, which scatter light in multiple directions, rather than reflecting it in a singular, coherent manner. Such reflections happen when light or other forms of waves or particles bounce off a surface, resulting in the dispersion of the incident rays at a variety of angles.

Shield 1130 can have an inherent degree of roughness, which prevents it from reflecting laser light 1150 in a single direction or fully absorbing the laser rays. Consequently, the diffusely reflected laser light from such a rough surface is dispersed in all directions. Such scattered reflection can cause the laser rays to heat the unit unevenly due to varied trajectories.

Adding lifter 1140 to the LAR tool can elevate the unit above the masking features, it can receive the laser light more uniformly. Even in the presence of laser diffraction, the diffracted rays would heat the surface's bottom rather than the top of the unit. In one example, diagram 1104 represents a system that can raise units 1120 to different levels. Raising the units a little above shield 1130 can still expose the heat surface of the unit. Raising the units higher can ensure even laser exposure and prevent uneven heating while not exposing the surface to reflections.

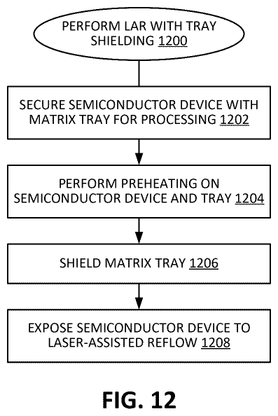

FIG. 12 is a flow diagram of an example of process for solder processing. Process 1200 represents an example of a process for performing LAR processing with tray shielding. Process 1200 illustrates a process that can be performed by an example of system 100.

In one example, the processing system secures a semiconductor device with a matrix tray for solder processing, at 1202. In one example, the system optionally performs preheating on the semiconductor device and the matrix tray, at 1204. In one example, the system shields the matrix tray to prevent thermal transfer to the matrix tray during solder reflow, at 1206. The system can then expose the semiconductor device to laser-assisted reflow, at 1208.

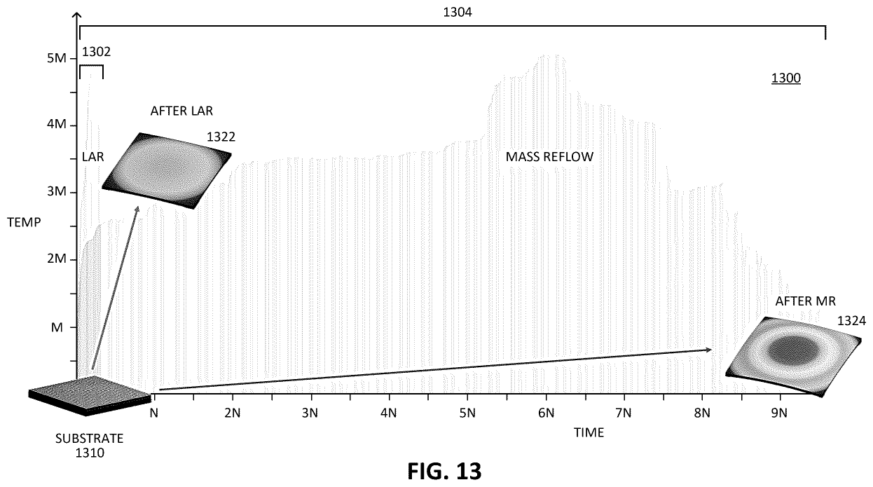

FIG. 13 is a diagram of an example of heat energy comparison between LAR and MR. Diagram 1300 illustrates an example of the energy efficiency of an example of the LAR process described as compared to mass reflow.

Diagram 1300 illustrates two portions, profile 1302 to represent the energy for LAR processing, and profile 1304 to represent the energy for MR processing. The total heat energy involved is indicated by the area under the temperature profile. The profiles are graphed on axes that are represented relatively rather than with specific numbers. The relative representation is because different materials and different implementations ca result in different numbers.

Diagram 1300 represents curves of temperature (TEMP) versus time. The temperature axis is marked with units of M, 2 M, . . . , 5 M, representing multiples of a value “M”. The time axis is marked with units of N, 2 N, . . . , 9 N, representing multiples of a value “N”. In one example, M and N are the same base value. In one example, M and N are different values.

In one implementation, the LAR process is 50 times faster than MR, resulting in a 90 times reduction in heat energy. Additionally, the reduced thermal stress exposure in LAR leads to less warpage, while MR can cause significant thermal strains. As one example, profile 1302 represents that LAR can last much less than a time of N, while the MR processing can last approximately 10 N.

Regarding the temperature, it can be observed that LAR processing and mass reflow processing can both have maximum temperatures that are approximately the same, 5 M. However, LAR processing quickly reaches a temperature of 5 M and quickly cools. MR processing, on the other hand, is at a temperature of at least 3M for a period of approximately 6 N, while LAR processing is finished in less than 1/10th that time.

Substrate 1310 represents the substrate of the semiconductor mounted in the tray used for the reflow processing. Substrate 1322 illustrates the relatively small amount of warpage of substrate 1310 after LAR processing. Substrate 1324 illustrates the greater warpage of substrate 1310 after MR processing. The prolonged exposure to high thermal stress in MR can permanently alter the material's structure due to the viscoelastic and viscoplastic nature of the PCB substrate.

The laser heating specifically targets the material and allows for quick heat dissipation, which in turn reduces residual stress. Conversely, the traditional MR process led to a significant increase in warpage. The increase is attributed to the hot air circulating in the oven during the MR process, which hinders quick heat dissipation and leads to more strain from residual stress.

In general with respect to the descriptions herein, in one aspect, a first system for solder processing includes: a matrix tray to hold a semiconductor device for solder processing; a laser-assisted reflow (LAR) laser source to provide collimated laser light to heat the semiconductor device; and a tray shield to shield the matrix tray from heat exposure from the laser light.

In accordance with one example of the first system, the matrix tray comprises a poly-ether sulfone (PES) tray. In accordance with any preceding example of the first system, in one example, the semiconductor device comprises a die stack. In accordance with any preceding example of the first system, in one example, the semiconductor device comprises a molded die. In accordance with any preceding example of the first system, in one example, the semiconductor device comprises a bare die. In accordance with any preceding example of the first system, in one example, the matrix tray is to hold an array of semiconductor devices for solder processing. In accordance with any preceding example of the first system, in one example, the tray shield comprises a shielding mask coupled to the matrix tray. In accordance with any preceding example of the first system, in one example, the tray shield comprises a laser mask on an output of the LAR laser source. In accordance with any preceding example of the first system, in one example, the tray shield comprises a coating on a surface of the matrix tray. In accordance with any preceding example of the first system, in one example, the first system includes: a heating chamber to preheat the semiconductor device and the matrix tray prior to exposure to the laser light. In accordance with any preceding example of the first system, in one example, the first system includes: a lifter to lift the semiconductor device above a surface of the matrix tray prior to exposure to the laser light.

In general with respect to the descriptions herein, in one aspect, a first method for solder processing comprising: securing a semiconductor device in a matrix tray for solder processing; exposing the semiconductor device to collimated laser light with a laser-assisted reflow (LAR) laser source to heat the semiconductor device; and shielding, with a tray shield, the matrix tray from heat exposure from the laser light.

In accordance with an example of the first method, the semiconductor device comprises a die stack, a molded die, or a bare die. In accordance with any preceding example of the first method, in one example, securing the semiconductor device in the matrix tray comprises securing an array of semiconductor devices for solder processing. In accordance with any preceding example of the first method, in one example, the tray shield comprises a shielding mask coupled to the matrix tray, or a laser mask on an output of the LAR laser source, or a coating on a surface of the matrix tray. In accordance with any preceding example of the first method, in one example, the first method includes: preheating the semiconductor device and the matrix tray in a heating chamber prior to exposure to the laser light. In accordance with any preceding example of the first method, in one example, the first method includes: lifting the semiconductor device above a surface of the matrix tray prior to exposure to the laser light.

In general with respect to the descriptions herein, in one aspect, a second system includes: a matrix tray to hold a semiconductor device for solder processing, the semiconductor device including a ball grid array (BGA) to solder; a laser-assisted reflow (LAR) laser source to provide collimated laser light to heat the semiconductor device to induce solder reflow for the BGA; and a tray shield to shield the matrix tray from heat exposure from the laser light during the solder reflow.

In accordance with one example of the second system, the matrix tray comprises a poly-ether sulfone (PES) tray. In accordance with any preceding example of the second system, in one example, the semiconductor device comprises a die stack. In accordance with any preceding example of the second system, in one example, the semiconductor device comprises a molded die. In accordance with any preceding example of the second system, in one example, the semiconductor device comprises a bare die. In accordance with any preceding example of the second system, in one example, the matrix tray is to hold an array of semiconductor devices for solder processing. In accordance with any preceding example of the second system, in one example, the tray shield comprises a shielding mask coupled to the matrix tray. In accordance with any preceding example of the second system, in one example, the tray shield comprises a laser mask on an output of the LAR laser source. In accordance with any preceding example of the second system, in one example, the tray shield comprises a coating on a surface of the matrix tray. In accordance with any preceding example of the second system, in one example, the second system includes: a heating chamber to preheat the semiconductor device and the matrix tray prior to exposure to the laser light. In accordance with any preceding example of the second system, in one example, the second system includes: a lifter to lift the semiconductor device above a surface of the matrix tray prior to exposure to the laser light.

In general with respect to the descriptions herein, in one aspect, a second method for solder processing includes: securing a semiconductor device in a matrix tray for solder processing, the semiconductor device including a ball grid array (BGA) to solder; exposing the semiconductor device to collimated laser light with a laser-assisted reflow (LAR) laser source to heat the semiconductor device to induce solder reflow for the BGA; and shielding, with a tray shield, the matrix tray from heat exposure from the laser light during the solder reflow.

In accordance with an example of the second method, the semiconductor device comprises a die stack, a molded die, or a bare die. In accordance with any preceding example of the second method, in one example, securing the semiconductor device in the matrix tray comprises securing an array of semiconductor devices for solder processing. In accordance with any preceding example of the second method, in one example, the tray shield comprises a shielding mask coupled to the matrix tray, or a laser mask on an output of the LAR laser source, or a coating on a surface of the matrix tray. In accordance with any preceding example of the second method, in one example, the second method includes: preheating the semiconductor device and the matrix tray in a heating chamber prior to exposure to the laser light. In accordance with any preceding example of the second method, in one example, the second method includes: lifting the semiconductor device above a surface of the matrix tray prior to exposure to the laser light.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. A system for solder processing comprising:
a matrix tray to hold a semiconductor device for solder processing;
a laser-assisted reflow (LAR) laser source to provide collimated laser light to heat the semiconductor device; and
a tray shield to shield the matrix tray from heat exposure from the laser light.

2. The system of claim 1, wherein the matrix tray comprises a poly-ether sulfone (PES) tray.

3. The system of claim 1, wherein the semiconductor device comprises a die stack.

4. The system of claim 1, wherein the semiconductor device comprises a molded die.

5. The system of claim 1, wherein the semiconductor device comprises a bare die.

6. The system of claim 1, wherein the matrix tray is to hold an array of semiconductor devices for solder processing.

7. The system of claim 1, wherein the tray shield comprises a shielding mask coupled to the matrix tray.

8. The system of claim 1, wherein the tray shield comprises a laser mask on an output of the LAR laser source.

9. The system of claim 1, wherein the tray shield comprises a coating on a surface of the matrix tray.

10. The system of claim 1, further comprising:
a heating chamber to preheat the semiconductor device and the matrix tray prior to exposure to the laser light.

11. The system of claim 1, further comprising:
a lifter to lift the semiconductor device above a surface of the matrix tray prior to exposure to the laser light.

12. A method for solder processing comprising:
securing a semiconductor device in a matrix tray for solder processing;
exposing the semiconductor device to collimated laser light with a laser-assisted reflow (LAR) laser source to heat the semiconductor device; and
shielding, with a tray shield, the matrix tray from heat exposure from the laser light.

13. The method of claim 12, wherein the semiconductor device comprises a die stack, a molded die, or a bare die.

14. The method of claim 12, wherein securing the semiconductor device in the matrix tray comprises securing an array of semiconductor devices for solder processing.

15. The method of claim 12, wherein the tray shield comprises a shielding mask coupled to the matrix tray, or a laser mask on an output of the LAR laser source, or a coating on a surface of the matrix tray.

16. The method of claim 12, further comprising:
preheating the semiconductor device and the matrix tray in a heating chamber prior to exposure to the laser light.

17. The method of claim 12, further comprising:
lifting the semiconductor device above a surface of the matrix tray prior to exposure to the laser light.
